(19) United States
(12) Patent Application Publication
(10) Pub. No.: US 2026/0142066 A1
(43) Pub. Date: May 21, 2026

(54) Coil device for a proximity sensor and method of producing such a coil device

(71) Applicant: Balluff GmbH, Neuhausen auf den Fildern (DE)

(72) Inventor: András Holló, Százhalombatta (HU)

(73) Assignee: Balluff GmbH, Neuhausen auf den Fildern (DE)

(21) Appl. No.: 19/368,219

(22) Filed: Oct. 24, 2025

(30) Foreign Application Priority Data
Nov. 21, 2024 (DE) 102024134339.7

(51) Int. Cl. H01F 17/00; G01B 7/02; H01F 41/04; H01F 41/061; H03K 17/95

(52) U.S. Cl. CPC H01F 17/0013; G01B 7/023; H01F 41/046; H01F 41/061; H03K 17/952; H01F 2017/002; H01F 2017/006; H01F 2017/0073; H03K 2017/9527

(57) ABSTRACT

A description is given of a coil device (10) for a proximity sensor, with a flexible circuit board (12), on which is arranged a conductor track (14) which has a first end region (20) and a second end region (22), wherein the flexible circuit board (12) is rolled up around a roller axis (R) or folded around a folding axis (F) such that the conductor track (14) forms a coil (46), with a rigid circuit board (18) for connecting at least one electronic component (24), and with an electrical connecting element (16), wherein the first end region (20) and the second end region (22) are each electrically connected to the rigid circuit board (18) by means of the electrical connecting element (16). It is thereby possible to produce a modular coil device.

### CROSS REFERENCE TO RELATED APPLICATIONS

This application claims priority to German Application No. 10 2024 134 339.7 filed Nov. 21, 2024, the disclosure of which is incorporated by reference in its entirety.

### FIELD OF INVENTION

The invention relates to a coil device for a proximity sensor and a method of producing such a coil device.

### PRIOR ART

Proximity sensors by means of which an object can be detected within a certain distance range are known from practice. Inductive proximity sensors are based on the principle of measuring changes caused by a metallic object in an oscillating electromagnetic field generated by a coil in order to detect the metallic object. While inductive proximity switches determine whether the object is within a certain distance of the sensor, inductive distance sensors can detect the distance and position of the object relative to the sensor.

In general, proximity sensors are based on the principle that an excitation coil of the proximity sensor can be supplied with electrical current in order to generate an oscillating electromagnetic field in the coil. If a metallic object is present near the proximity sensor, eddy currents occur near the object's surface, induced by the coil's changing magnetic field. This in turn leads to a change in the coil's electromagnetic field in terms of its geometry and intensity. This change in the electromagnetic field can be detected by measuring an induced voltage in the excitation coil and/or in one or more separate detection coils of the proximity sensor.

Such coils of a proximity sensor can, for example, be a wire coil, a coil structured on and/or in a rigid circuit board, or a coil structured on and/or in a flexible circuit board. The latter “flexible coil” can, for example, be manufactured according to DE 10 2008 012 120 B4. According to DE 10 2019 115 405 A1, different interconnections of several such “flexible coils” can be implemented on the circuit board of the “flexible coil”. These three manufacturing technologies each require different manufacturing processes for the coils, so the production of a proximity sensor requires different manufacturing equipment and processes depending on the different coil type. To minimize the costs of manufacturing a proximity sensor, it is best to standardize and unify coil devices and their manufacturing so that they are suitable for different types of proximity sensors or other product types which use similar coils.

### DISCLOSURE OF THE INVENTION

The invention is based on the object of providing a coil device, a proximity sensor and a method of producing a coil device which are particularly cost-effective.

This object is achieved by a coil device, a proximity sensor and a method of producing a coil device according to the independent claims. Advantageous embodiments are specified in the subclaims.

According to a first aspect, provision is made for a coil device for a proximity sensor, with a flexible circuit board on which is arranged a conductor track which has a first end region and a second (in particular other) end region, wherein the flexible circuit board is rolled up around a roller axis or folded around a folding axis such that the conductor track forms a coil, with a rigid circuit board for electrically connecting at least one electronic component, and with an electrical connecting element, wherein the first end region and the second end region are each electrically connected to the rigid circuit board by means of the electrical connecting element.

It is thereby possible to produce a modular coil device which can work, for example, as an excitation and/or detection element for any type of sensor (in particular an inductive proximity sensor or a gradiometer sensor or gradient sensor), which has three standardizable components: A coil based on a flexible circuit board, a rigid circuit board on which electronic components for the proximity sensor can be placed, and an electrical connecting element for the electrical and mechanical connection of the two circuit boards.

The coil can be scaled in size, for example in diameter, particularly easily due to the rolled up or folded circuit board, so different sized sensor housings, such as an M18, M12, M8, etc. sensor housing, can be used. It is also possible to implement a few basic coil types with the flexible circuit board. Since the flexible circuit board is oriented differently than a coil based on a rigid circuit board, new coil types with a wide range of electrical properties can be realized.

The rigid circuit board can serve as a configuration module for the respective sensor type since the corresponding electrical connection of the coil to the rigid circuit board can enable different applications of the coil device. Depending on the number and type of usable connecting elements, these can also be standardized. The term “standardized” in this context can be understood to mean that production or the competencies can be standardized. In particular, it does not mean that a DIN standard or a standard specification must be met.

Overall, the necessary manufacturing steps, logistics in the manufacturing process and the type of manufacturing tools used can therefore be reduced or minimized due to the modular design. Furthermore, an entire product portfolio can be realized with a few variations of the three components, thus reducing the complexity of manufacturing different proximity sensors. Furthermore, the development of further products based on this modular coil device can be accelerated since less planning time may be required for redesigning components. For example, it may only be necessary to redesign the rigid circuit board since the coil and the connecting element can be reused.

Overall, the coil device according to the invention can therefore make both the production of the coil device and the coil device and the proximity sensor particularly cost-optimized and/or cost-effective.

The flexible conductor track can be rolled or folded at least once, in particular several times, across its entire circumference or completely (in particular in an overlapping manner). The coil formed by the conductor track can have as many windings as the number of times the circuit board can be rolled up or folded around the folding axis. The roller axis or folding axis can run perpendicularly to the coil plane here, that is to say the plane in which the coil can substantially extend.

In one embodiment, the connecting element has soldering tin or solder paste. This measure enables a direct connection between the two circuit boards.

In one embodiment, the connecting element has at least one flexible printed circuit (FPC) connector, allowing for a wide range of connectors of different sizes and mountability. For example, surface-mountable FPC connectors can be soldered directly onto the rigid circuit board together with other electronic surface-mounted devices (SMDs) or components of the proximity sensor. Furthermore, soldering of the flexible circuit board and the rigid circuit board can be dispensed with. A mechanical and electrical connection can be achieved by assembling the relevant components in a quickly completable production step. The end region of the flexible circuit board, and thus the end region of the conductor track, can be inserted into a corresponding slot in the FPC connector here and held in place with either a locking mechanism or another mechanical fixing mechanism so that the end region cannot slip out of the connector. Although the FPC connector, as an additional component, may increase manufacturing costs, the coil device manufactured in this way may be more cost-effective than a coil device in which the two circuit boards can be soldered together.

In one embodiment, the roller axis or folding axis of the flexible circuit board runs substantially true parallel or parallel to an extension of the rigid circuit board. In such an embodiment, the coil plane or the body of the flexible circuit board can therefore run transversely, in particular perpendicularly, to the extension of the rigid circuit board. An end region of the flexible circuit board, on which the end regions of the conductor track are arranged, can be bent or folded in such a way here that the end regions of the conductor track can be arranged parallel to the rigid circuit board, for example in order to simplify the soldering of the two circuit boards. This measure can ensure that the length of the rigid circuit board is not affected by the diameter of the coil. The electronic components of the proximity sensor can be accommodated particularly easily on the resulting enlarged surface of the rigid circuit board.

In one embodiment, the roller axis or folding axis of the flexible circuit board runs substantially transversely, in particular perpendicularly, to an extension of the rigid circuit board. In such a configuration, the end regions of the conductor track and also of the flexible circuit board can be bent such that they run parallel to the extension of the rigid circuit board. In this configuration of the coil arrangement, the available surface area of the rigid circuit board on which the electronic components for the proximity sensor can be placed may be limited. However, the coil device can be implemented very compactly and integrated easily into a housing.

In one embodiment, a contact point for the first end region of the conductor track is arranged on one side of the rigid circuit board and a contact point for the second end region of the conductor track is arranged on a second (in particular other) side of the rigid circuit board. This embodiment can particularly easily enable the rigid circuit board to be arranged parallel to the roller axis or folding axis. In other words, the rigid circuit board can be connected on two different sides to different end regions of the conductor track.

In one embodiment, contact points for the first and second end regions of the conductor track or for the connecting element are arranged on one side of the rigid circuit board, wherein a contact point for the at least one component is arranged on a second (in particular other) side of the rigid circuit board. In other words, the rigid circuit board can be connected to the conductor track on just one side, while the component can be arranged on the other side. In this relative arrangement of the two circuit boards, they can be connected particularly easily. This embodiment can be used particularly easily together with the rigid circuit board being arranged transversely, in particular perpendicularly, to the roller axis or folding axis.

In one embodiment, there is arranged on the flexible circuit board at least one second, that is to say further, conductor track which has a first end region and a second end region, wherein the conductor track and the at least second conductor track run substantially adjacent to one another (in particular on the same side of the flexible circuit board), wherein the at least second conductor track forms an at least second coil. In particular, the conductor tracks can run substantially parallel to one other (for example up to the end regions). This allows the number of coils in the coil device to be scalable in order to improve the excitation of the electric field and/or detection of the induced voltage. In particular, with the same size of coil device, more coils can be accommodated in the coil device compared to wire coils or a rigid circuit board which has coils. Using the flexible circuit board with multiple conductor tracks can also make it easier to achieve axially offset and precisely positioned coils compared to the other two coil types.

The rigid circuit board can have corresponding contact points as described above. Since the more rigid circuit board serves to interconnect the different coils, the electrical interconnection of multiple coils in the manufacturing process can be standardized and thus simplified.

In one embodiment, the first and second end regions of the conductor track and the first and second end regions of the at least second conductor track are electrically connected to the rigid circuit board in such a way that the first coil and at least second coil are electrically separated coils. This allows electrically independent coils to be configured, depending on the desired application, by making corresponding contact on the rigid circuit board. If required, exactly as many electrically independent coils can be generated as there are coils on the flexible circuit board.

In one embodiment, the first and second end regions of the conductor track and the first and second end regions of the at least second conductor track are electrically connected to the rigid circuit board in such a way that the first coil and second coil are shared coils. For this purpose, an end region of the first coil (for example on a first side of the rigid circuit board) can be electrically connected to an end region of the second coil (for example on a second or other side of the rigid circuit board), or an end region of the second coil (for example on the first side of the rigid circuit board) can be electrically connected to an end region of the first coil (for example on the second or other side of the rigid circuit board). This can create an assembled coil with three terminals. The coil device thus realized can be used in a Hartley oscillator.

In one embodiment, the first and second end regions of the conductor track and the first and second end regions of the at least second conductor track are electrically connected to the rigid circuit board in such a way that the first coil and second coil are connected in series. This allows for the formation of an assembled coil which has a larger number of windings and can generate a correspondingly stronger electromagnetic field. Furthermore, the inducible voltage can be increased.

The three embodiments described above can make it possible to easily and flexibly change the number, design and functions of the resulting coils since only the contacts of the first and second coils on the rigid circuit board need to be adjusted. In other words, based on the same coils formed by the flexible circuit board with the conductor tracks, a wide variety of coil devices can be created simply by changing the configuration of the rigid circuit board with its contact points. This avoids contacting the first and second coils directly on the flexible circuit board, which is technically more difficult due to their positional alignment. In addition, electronic components may be placeable directly on the rigid circuit board and do not also need to be contacted with the flexible circuit board.

In one embodiment, the coil device further comprises a core element, which may have or be formed from a ferromagnetic material, in particular ferrite, wherein the core element may be arranged in a coil plane inside the coil. In this context, ferrite may belong to the class of ferrites and be a soft or hard magnetic ferromagnetic material, usually a ceramic material. In particular, the selected ferrite material may be hard magnetic. In particular, iron may not to be used as the material for the core element. The core element can fill the inside of the coil, which can be defined by the conductor track or the flexible circuit board, and an external surface of the core element, which can extend transversely (in particular perpendicularly) to the coil plane, can be adapted to the interior shape of the rolled or folded flexible circuit board. The core element can also be configured as a plate, arranged parallel to the coil plane and fill the inside of the coil.

The coil device can further have a sheath which can surround the rolled up or folded flexible circuit board and thus the coil laterally on its outside and in the cover region. The sheath can also comprise or be made from the same or a different ferromagnetic material as the core element. In particular, the ferromagnetic material can comprise (for example hard magnetic) ferrite. In particular, iron may not to be used as the material for the sheath. The sheath can have a side element which can surround and/or cover the outside of the flexible circuit board. Furthermore, the sheath can have a cover element which covers one side of the coil. The sheath can also have a further cover element which covers the other side of the coil. The height of the core element can be dimensioned such that the cover element(s) and the core element are flush with one another. The core element and the sheath can be configured as a single piece.

These two measures described above may enable the electromagnetic field of the coil to be directed towards the object to be detected and to increase the field strength of the electromagnetic field of the coil. This can increase the range of the proximity sensor and detect objects which are at a greater distance from the sensor. This can be particularly advantageous for an inductive proximity switch.

In one embodiment, the flexible circuit board has two lugs which extend parallel to the roller axis or folding axis, wherein the end regions of the conductor track are each arranged on a different one of the two lugs (in particular on the outside facing away from the coil or the axis or the coil interior). In other words, the first end region can be arranged on the first lug and the second end region on the second lug. The lugs can be arranged in opposite regions of the coil when viewed from above the coil plane. This allows the contacting of the coil to be provided at a distance from the coil plane so that electrical interference with the field generated by the coil can be minimized. In particular, the core element can in each case have an (in particular semicircular) recess in the lug region which opens or widens outwards (that is to say away from the coil interior) and can extend through one of the two lugs in each case. If only one cover element of the sheath is present, the cover element can be arranged on the same side of the coil as the lugs.

In one embodiment, a cross section of the rolled up or folded flexible circuit board running transversely, in particular perpendicularly, to the roller axis or folding axis is round, oval, rectangular or square. This allows the respective coil shape to be advantageously adapted to the design of the proximity sensor.

In one embodiment, the conductor track runs in a straight, wavy or zigzag pattern on the flexible circuit board. This allows the inductance and/or the resistance and/or the coupling factor of the formed coil to be adjusted in order to specifically optimize the electrical properties of the coil for a desired use.

In one embodiment, the flexible circuit board is configured to be multi-layered, wherein the conductor track is arranged in a first layer of the flexible circuit board, wherein an at least second conductor track is arranged in at least a second layer of the flexible circuit board, wherein the at least second conductor track forms an at least second coil, wherein end regions of the first and second conductor tracks are arranged on an (in particular common) external surface of the flexible circuit board by means of plated through-holes. This can increase the number or density of the conductor tracks and thus the performance of the coil to be formed overall. The end points of the conductor tracks can be arranged on a conductive outer layer of the circuit board which can be implemented with or without a conductor track.

In one embodiment, the conductor track is configured to be at least two-stranded in its middle region, in particular to have a plurality of strands. In other words, the individual strands of the conductor track can each have a common first and second end point. This allows the conductor track to form a stranded wire. This measure can be advantageous for certain sensor applications despite increased manufacturing costs. In particular, the strands can be implemented on the circuit board in such a way that they fan out at acute angles from an (in particular straight) end region and then extend adjacent, in particular parallel, to each other in a central region of the circuit board.

It is understood that the at least second coil can be implemented in the same way as described above (for example with regard to its cross section, its course and/or its number of strands).

The flexible circuit board can, for example, comprise or consist of polyimide. This material is able to provide the necessary structural integrity for the coil.

The rolled or folded coil can, for example, be held in shape by means of adhesive or mechanical fixing.

According to a second aspect, provision is made for a proximity sensor which has a coil device according to the first aspect, wherein the proximity sensor is an inductive proximity switch or an inductive distance sensor.

According to a third aspect, provision is made for a method for producing a coil device for a proximity sensor comprising the steps of providing a flexible circuit board on which is arranged a conductor track which has a first end region and a second end region, wherein the flexible circuit board is rolled up around a roller axis or folded around a folding axis such that the conductor track forms a coil, providing a rigid circuit board for electrically connecting at least one electronic component, providing an electrical connecting element, and electrically connecting each of the first end region and the second end region to the rigid circuit board by means of the electrical connecting element.

The rolling up or folding of the flexible circuit board can be carried out, for example, by means of a plastic coil former or without using such a former. The flexible circuit board can be fixed as described above by means of mechanical fixing or adhesive.

If solder paste is used as a connecting element, the solder paste can be applied to one or both circuit boards. The two circuit boards can then be positioned relative to each other. Applying heat can melt the solder paste, establishing the electrical and mechanical contact between the two circuit boards. To connect the two circuit boards in this way, the solder paste must be applied immediately before joining to avoid contamination of the solder paste.

If solder paste is used as a connecting element in reflow soldering, it is possible to apply the solder paste before the flexible circuit board is connected to the rigid circuit board. In this process, the solder paste can be applied to the rigid circuit board, heated and then cooled. Afterwards, as a separate manufacturing step, flux can be added to the already “soldered” surface to assist the reflow. After adding the flux, the flexible circuit board can be positioned on the rigid circuit board. When heated, the solder paste melts. After cooling, the two circuit boards are connected in the same way as if solder paste were used alone.

The two circuit boards can also be soldered using soldering tin as the connecting element. In this variant, use can therefore be made of solid solder material which can enable easy connection of the two circuit boards.

### BRIEF DESCRIPTION OF THE DRAWINGS

Exemplary embodiments of the invention are illustrated in the drawings and explained in more detail in the following description. In the figures:

FIG. 1 shows a schematic view of a coil device for a proximity sensor according to a first exemplary embodiment;

FIGS. 2A, 2B show an example of a flexible circuit board of the coil device in FIG. 1;

FIGS. 3A, 3B show further examples of the flexible circuit board in FIG. 1;

FIGS. 4A, 4B show a further example of the flexible circuit board in FIG. 1;

FIG. 5 shows a further example of the flexible circuit board in FIG. 1 in plan view;

FIG. 6 shows a further example of the flexible circuit board in FIG. 1 in plan view;

FIG. 7 shows a perspective view of a further example of the flexible circuit board in FIG. 1;

FIG. 8 shows the flexible circuit board in FIG. 7 with a core element and a sheath;

FIGS. 9A, 9B show a first and second side of an example of a rigid circuit board in FIG. 1 in plan view;

FIGS. 10A, 10B show a first and second side of a further example of a rigid circuit board in FIG. 1 in plan view;

FIGS. 11A, 11B show an example of the coil device in FIG. 1 in section and as an enlarged sectional view;

FIG. 12 shows a first side of a further example if a rigid circuit board in FIG. 1 in plan view;

FIGS. 13A, 13B show an example of the coil device in FIG. 1 in section and as an enlarged sectional view;

FIG. 14 shows a method according to an exemplary embodiment for manufacturing a coil device in FIG. 1; and

FIG. 15 shows a block diagram for an assembly of components for use in the method in FIG. 14.

### EMBODIMENTS OF THE INVENTION

The same or similar components or elements are provided with the same reference numerals.

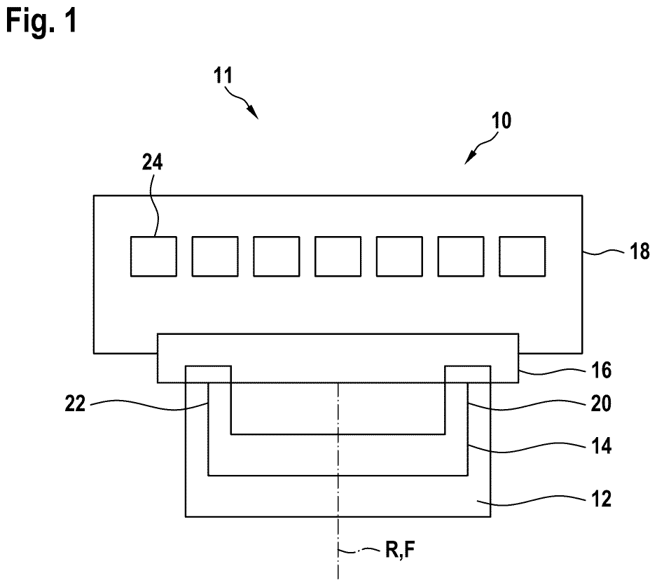

A coil device according to an exemplary embodiment, designated by the reference numeral 10 in FIG. 1 and suitable for a proximity sensor 11, has a flexible circuit board 12 which is rolled up completely several times so as to overlap around a roller axis R or folded completely several times so as to overlap around a folding axis F, and on which a conductor track 14 is arranged. The conductor track 14 forms a coil. The circuit board 12 is electrically connected to a rigid circuit board 18 by means of an electrical connecting element 16 such that a first end region 20 of the conductor track 14 and a second end region 22 of the conductor track 14 are coupled to the rigid circuit board 16 by means of the connecting element 16. Several electronic components 24 are arranged and contacted on the rigid circuit board 18, for example in order to enable a power supply to the conductor track 14 and/or an evaluation of a voltage induced in the conductor track 14. For the sake of clarity, only one component is designated by the reference number 24.

The connecting element 16 is configured as an FPC connector. For this purpose, the end regions 20, 22, which are bent from a coil plane, are inserted into corresponding slots of the FPC connector 16. The coil plane runs perpendicularly to the axis R, F. The FPC connector 16 is inserted into the rigid circuit board 18 by pins.

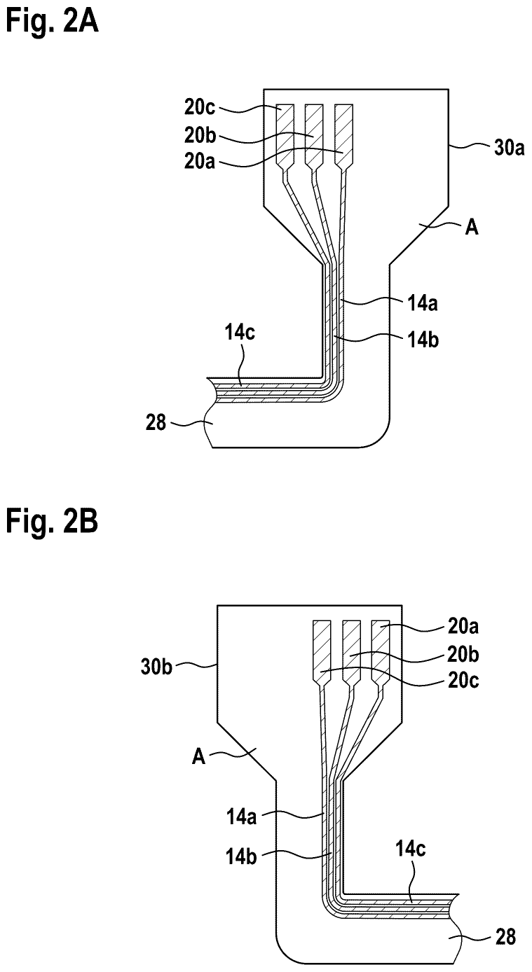

The non-rolled or non-folded circuit board 12 shown in FIGS. 2A, 2B has an elongated central region 28 (partially shown), the two end regions of which are each configured as lugs 30a, 30b and extend approximately perpendicularly to the middle region 28. The lugs 30a, 30b widen in diameter compared to the middle region 28 towards their ends. Three conductor tracks 14a-14c extend from their first respective end regions 20a-20c along the lug 30a and the middle region 28 to their second end regions 22a-22c on the lug 30b on a common outside A of the circuit board 12. Ends of the end regions 20a-20c, 22a-22c are configured as contact points with an enlarged surface area relative to the diameter of the conductor track 12.

It is also possible for the circuit board 12 in FIGS. 2A, 2B to be configured to be multi-layered. Only the conductor track 14a is structured in a first outer layer. The conductor track 14b is formed in a second conductive layer which is arranged inside the circuit board 12 below the outer layer and electrically insulated from it. The conductor track 14c is formed in a third conductive layer which is arranged inside below the second layer and electrically insulated from it. The conductor tracks 14b, 14c are connected to the conductor track 14a via corresponding plated through-holes.

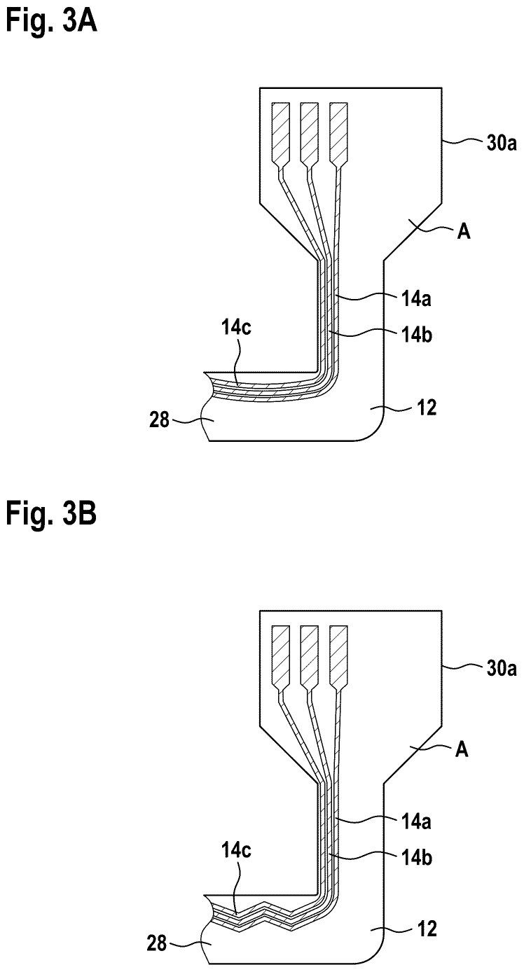

The two examples of the circuit board 12 shown in FIGS. 3A, 3B are configured similarly to the circuit board 12 in FIGS. 2A, 2B and differ only in that the conductor tracks 14a-14c in the middle region 28 do not run in a straight line, but rather in a wavy shape (FIG. 3B) or in a zigzag shape (FIG. 3B).

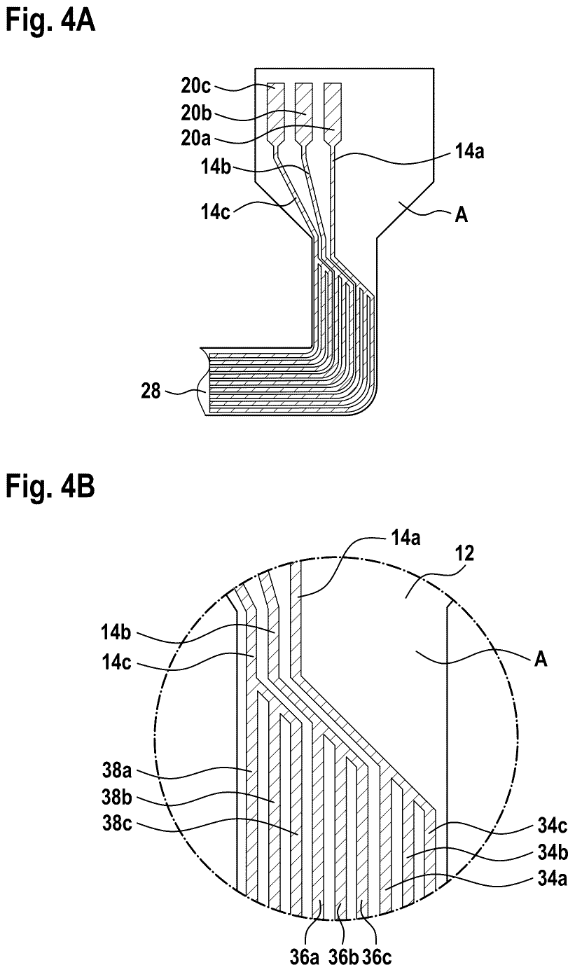

In the example of the circuit board 12 shown in FIGS. 4A, 4B which is configured similarly to the circuit board 12 in FIGS. 2A, 2B, each conductor track 14a-14c has one strand in its end region 20a, 20b, 20c, 22a, 22b, 22c. In contrast to the conductor tracks 14a-14c in FIGS. 2A, 2B, each of the conductor tracks 14a-14c fans out in three strands in the region of the lugs 30a, 30b toward the middle region 30, so that nine conductor track strands 34a-34c, 36a-36c, 38a-38c run in the middle region 28 of the circuit board 12. The branching is configured such that a conductor track strand 34a-34c, 36a-36c, 38a-38c splits off at an acute angle from a respective adjacent conductor track strand 34a-34c, 36a-36c, 38a-38c.

Alternatively, the nine-strand coil can be formed by the circuit board in FIGS. 4A, 4B being configured to be multi-layered. The end regions 20a-20c, 22a-22c and the strands 34a, 36a, 38a are structured in a first outer layer. The strands 34b, 36b, 38b are formed in a second conductive layer, which is arranged inside the circuit board 12 under the outer layer and electrically insulated from it, each strand running in the middle region 28 to the fan-out points in FIGS. 4A, 4B. The strands 34c, 36c, 38c are formed in a third conductive layer, which is arranged inside under the second layer and electrically insulated from it, each strand running in the middle region 28 to the fan-out points in FIGS. 4A, 4B. The strands 34b, 36b, 38b and 34c, 36c, 38c are connected to the strands 34a, 36a, 38a via corresponding plated through-holes.

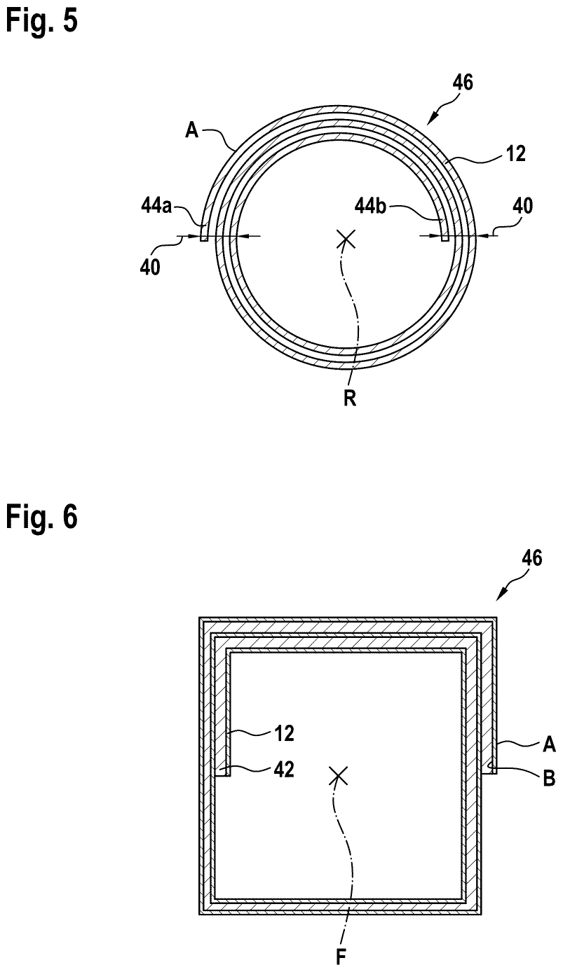

As shown in FIGS. 5 and 6, a cross section of the rolled up or folded circuit board 12 running perpendicularly to the roller axis R or folding axis F can be configured to be round (FIG. 5) or square (FIG. 6). Alternatively, the cross section can be oval or rectangular. The flexible circuit board 12 can be held in its rolled up or folded position either mechanically with clamps 40 or by means of an adhesive 42. The mechanical clamps are provided at end regions 44a, 44b of the circuit board 12. The conductor track 14 runs on the outside A of the rolled up flexible circuit board 12. The adhesive 42 is applied to an inside B of the flexible circuit board 12 so that the conductor track 14 lies under the adhesive 42 in the overlapping region of the circuit board 12. The rolled up or folded circuit board forms a coil 46. The circuit board 12 or conductor track 14 can be rolled up or unfolded with multiple windings so that the coil 46 formed from the conductor track 14 has multiple windings.

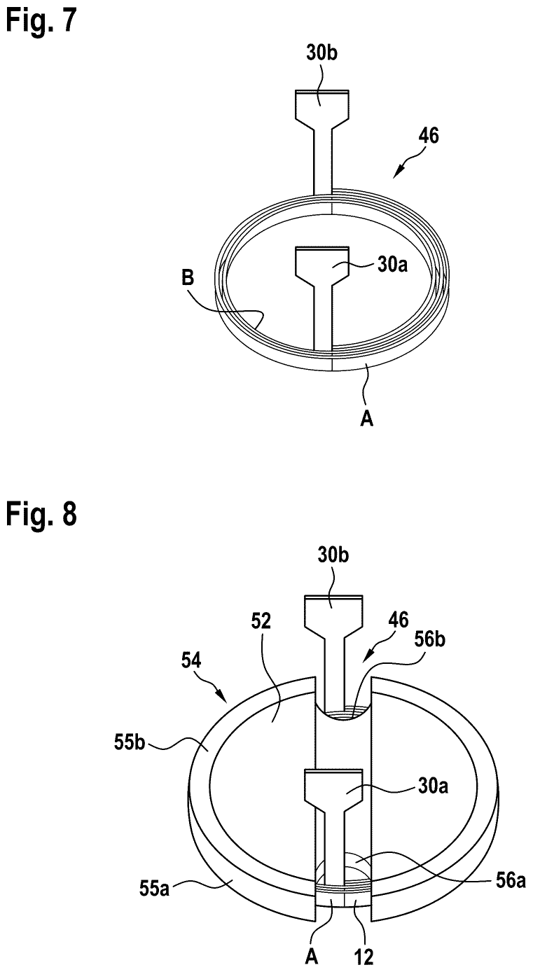

FIG. 7 shows a perspective view of the rolled up circuit board 12 together with the lugs 30a, 30b. The conductor track (not shown) runs on the outside A of the circuit board 12.

In FIG. 8, a plate-shaped, round core element 52 made of a hard magnetic ferromagnetic material (in particular a ferrite) is arranged inside the coil 46 in the coil plane. Furthermore, a sheath 54, which is also made of the same ferromagnetic material, encloses the formed coil 46 from FIG. 7. The sheath 54 has a side element 55a which covers the outside A of the flexible circuit board 12. Furthermore, the sheath 54 has an annular cover element 55b which covers one side of the coil 46. The height of the core element 52 is dimensioned such that the cover element 55b and the core element are flush with one another. The core element 52 and the sheath 54 are configured as a single piece. In the region of the bending points of the lugs 30a, 30b, the core element 52 has in each case a recess 56a, 56b through which a different one of the lugs 30a, 30b extends perpendicularly away from the coil plane. The cover element 55b is arranged on the same side of the coil 46 as the lugs 30a, 30b.

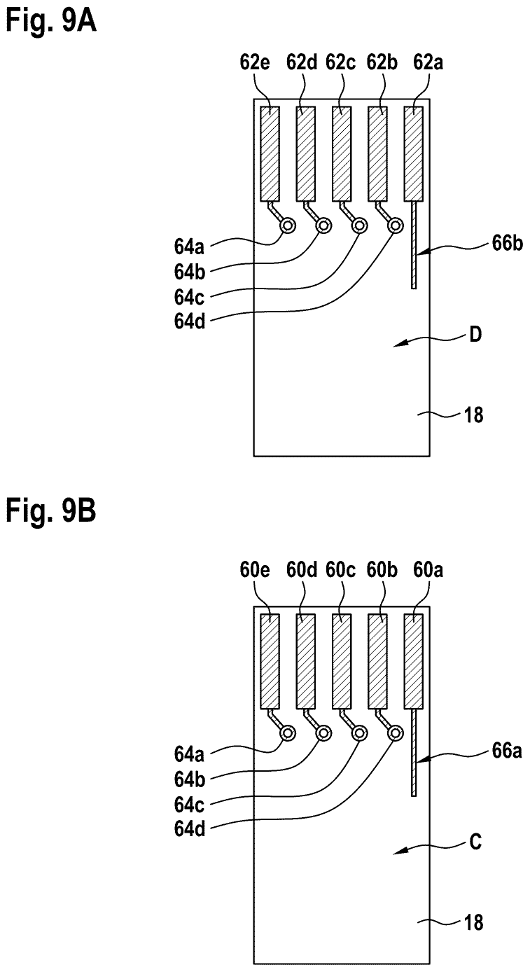

FIGS. 9A, 9B show a first side C and a second side D of an example of a rigid circuit board 18 which is connected to a flexible circuit board 12 (not shown) which has five parallel conductor tracks 14a-14e. The end regions 20a-20e and 22a-22e of the conductor tracks 14a-14e are soldered to corresponding contact points 60a-60e and 62a-62e, respectively, on the circuit board 18 by means of a connecting element 16 in the form of solder paste. The contact points 60 a-60e, 62 a-62e are in turn connected by means of plated through-holes 64a-64d, 66a-66d which are provided on the rigid circuit board 18 so that the five coils which are formed by the five conductor tracks 14a-14e on the flexible circuit board 12 are connected in series and a single assembled coil is formed. A coil end 66a, 66b which is arranged on each side C, D of the circuit board 18 can be used to contact the component 24.

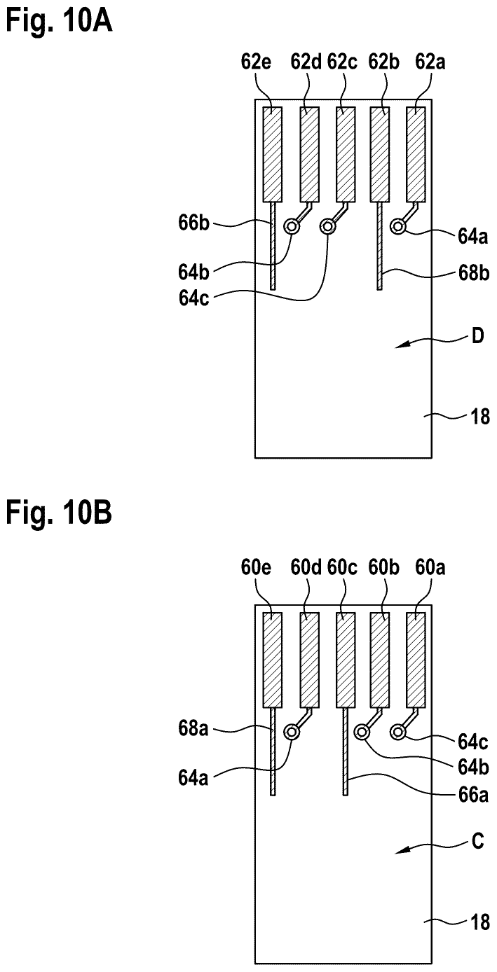

The example of the rigid circuit board 18 shown in FIGS. 10A, 10B is configured similarly to the example in FIGS. 9A, 9B. However, only three plated through-holes 64a-64c are present, these (seen from the left) connecting the first conductor track 14a with the second and third conductor tracks 14b, 14c and the fourth conductor track 14d with the fifth conductor track 14e, respectively. Consequently, two assembled coils are formed by means of the contacting of the rigid circuit board 18, each of which is electrically separated from the other. Corresponding coil ends 66a, 66b and 68a, 68b of the first and second coils are structured on the rigid circuit board.

It is also possible to connect the end 66b of the first coil on the side D to the end 68a of the second coil on the second side C of the rigid circuit board 18, or the end 68b of the second coil on the first side D to the end 66a of the first coil on the second side C. Such a circuit would create a common coil with three terminals which can be used, for example, in a Hartley oscillator.

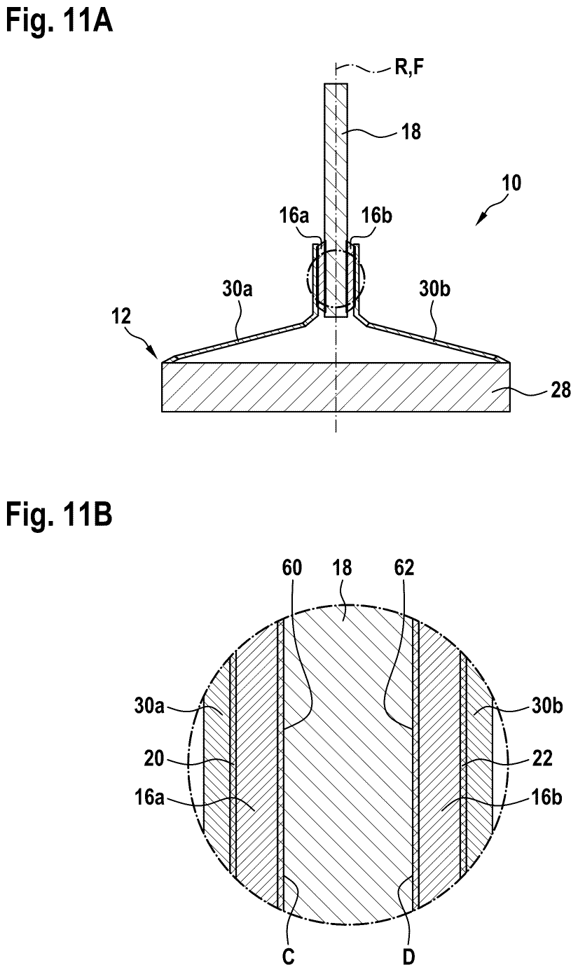

In the exemplary embodiment of the coil device 10 shown in FIGS. 11A, 11B, the rigid circuit board 18 is arranged perpendicularly to the coil plane which intersects the rolled up or folded flexible circuit board 12, and along the axis R, F. A longitudinal extension of the rigid circuit board 18 thus runs parallel to or in the direction of the axis R, F of the circuit board 12. The lugs 30a, 30b are bent at an acute angle from the coil plane, while the end regions of the lugs 30a, 30b are bent towards the rigid circuit board 18 and arranged parallel to the rigid circuit board 18. To connect the circuit board 12 to the rigid circuit board 18, soldering tin 16a, 16b is provided as a connecting element, this being provided between a copper contact point 60, 62 on each side C, D of the rigid circuit board 18 and the ends 20, 22 on the flexible circuit board 12.

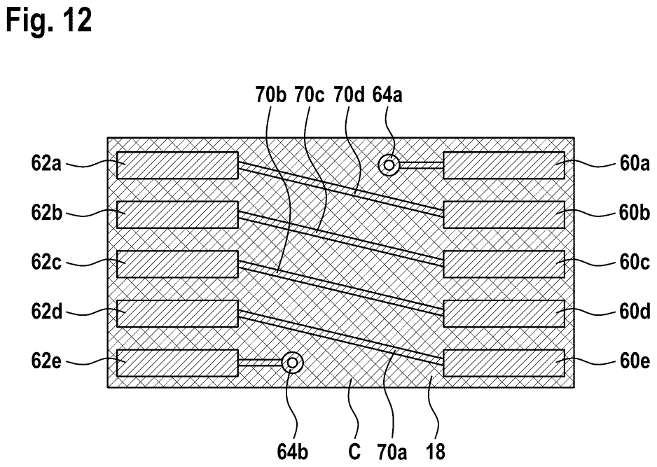

In the example of the rigid circuit board 18 shown in FIG. 12, contact points 60a-60e and 62a-62e are arranged on one side C, to which the end regions 20a-20e and 22a-22e of the conductor tracks 14a-14e are coupled. The conductor tracks 14a-14e thus form a series-connected coil. The contact points 60b, 62a and 60c, 62b and 60d, 62c and 60e, 62d are connected to one another by means of conductor strands 70a-70d structured on the rigid circuit board 18. Plated through-holes 64a, 64b connect the assembled coil to electronic components 24 which are arranged on the other side of the rigid circuit board 18.

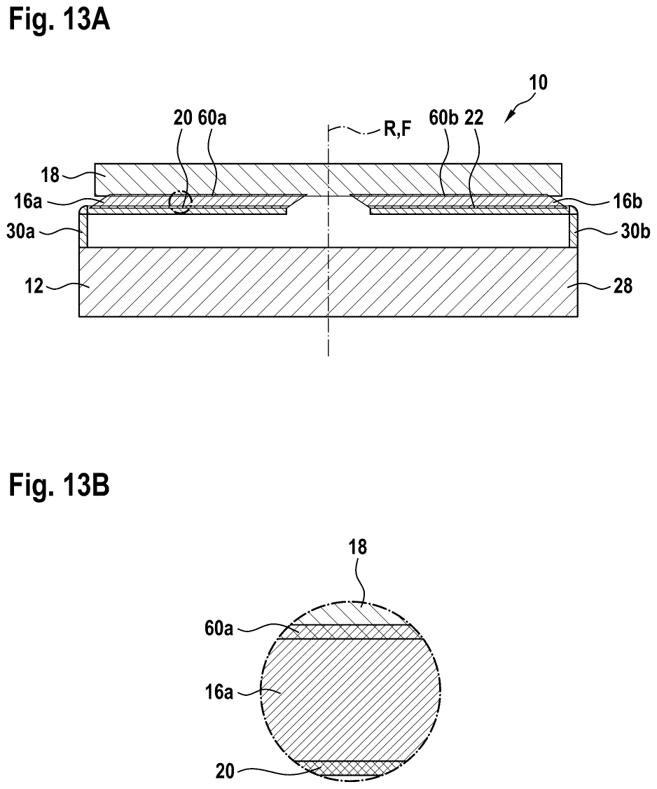

In the exemplary embodiment of the coil device 10 shown in FIGS. 13A, 13B, the flexible circuit board 12 and the rigid circuit board 18 are arranged parallel to one another. In other words, the axis R, F runs perpendicularly to the rigid circuit board 18. The lugs 30a, 30b are folded such that they are bent twice at a right angle to the circuit board 12 and then run parallel to the flexible circuit board 12. The connecting element 16a,16b in the form of soldering tin is soldered between the corresponding contact points 60a, 60b on the rigid circuit board 18 and the end regions 20, 22 of the conductor track 14. The end regions 20, 22 are configured in this case as solder contact points.

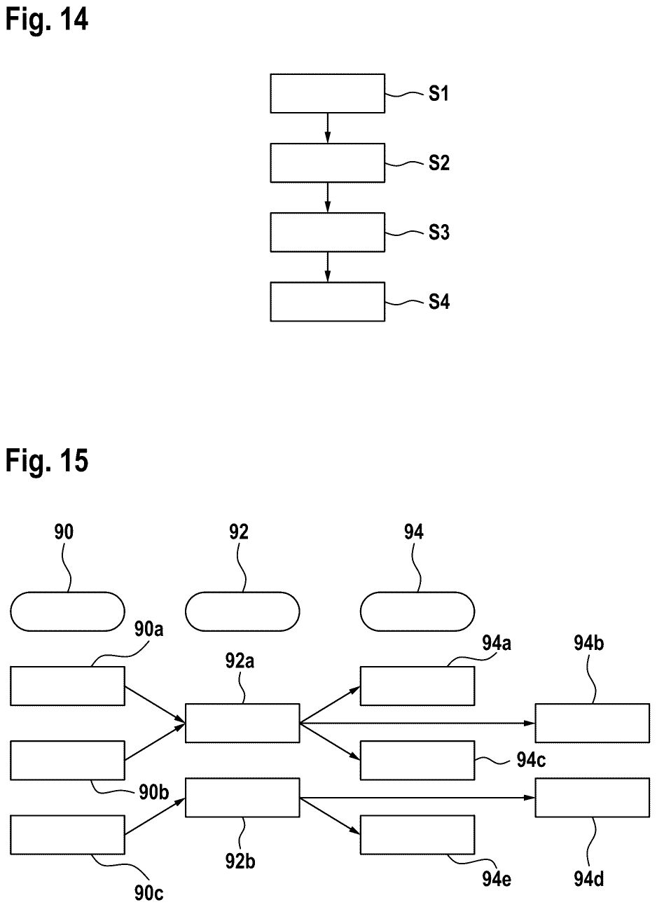

In the method shown in FIG. 14 for producing a coil device 10 for a proximity sensor 11, a flexible circuit board 12 on which a conductor track 14 is arranged is provided in a first step S1. The circuit board 12 is rolled up completely once or several times around a roller axis R or folded completely once or several times around a folding axis F such that the circuit board 12 forms a coil 46 with the conductor track 14. In a second step S2, a rigid circuit board 18 is provided. In a further method step S3, an electrical connecting element 16 is provided. In a subsequent method step S4, the flexible circuit board 12 is connected to the rigid circuit board 16 such that a first end region 20 and a second end region 22 of the conductor track 14 are electrically connected to the rigid circuit board 18 by means of the connecting element 16.

Steps S1-S3 can be performed in any order.

FIG. 15 illustrates that the coil device 10 can be formed modularly from three components, namely a coil component 90, a connecting element component 92 and a configuration circuit board component 94. Coil components 90 can represent different types of circuit board 12 with the conductor track 14, as described, for example, in FIGS. 2A to 8. Three coil components 90a-90c are shown as examples. A connecting element in the form of soldering tin or solder paste (reference numeral 92a) or a connecting element 16 in the form of an FPC connector (reference numeral 92b) can be selected as connecting element components 92a, 92b. A desired rigid circuit board 18 can then be selected as configuration circuit board components 94a-94e, as described, for example, in FIGS. 9A-13B. In this way, proximity sensors 11 can be constructed in a particularly simple modular manner.

1. Coil device (10) for a proximity sensor (11), with:
a flexible circuit board (12), on which is arranged a conductor track (14) which has a first end region (20) and a second end region (22), wherein the flexible circuit board (12) is rolled up around a roller axis (R) or folded around a folding axis (F) such that the conductor track (14) forms a coil (46);
a rigid circuit board (18) for connecting at least one electronic component (24), and
an electrical connecting element (16), wherein the first end region (20) and the second end region (22) are each electrically connected to the rigid circuit board (18) by means of the electrical connecting element (16).

2. Coil device (10) according to claim 1, wherein the connecting element (16a, 16b) has soldering tin or solder paste.

3. Coil device (10) according to claim 1, wherein the connecting element (16) has at least one FPC connector.

4. Coil device (10) according to claim 1, wherein the roller axis (R) or folding axis (F) of the flexible circuit board (12) runs substantially parallel to an extension of the rigid circuit board (18).

5. Coil device (10) according to claim 1, wherein the roller axis (R) or folding axis (F) of the flexible circuit board (12) runs substantially transversely, in particular perpendicularly, to an extension of the rigid circuit board (16).

6. Coil device (10) according to claim 1, wherein a contact point (60a-60e) for the first end region (20) of the conductor track (14) is arranged on one side (C) of the rigid circuit board (18) and a contact point (62a-62e) for the second end region (22) of the conductor track (14) is arranged on a second side (D) of the rigid circuit board (18).

7. Coil device (10) according to claim 1, wherein contact points (60a-60e, 62a-62b) for the first and second end regions (20, 22) of the conductor track (14) are arranged on one side (C) of the rigid circuit board (18), wherein a contact point for the at least one electronic component (24) is arranged on a second side of the rigid circuit board (18).

8. Coil device (10) according to claim 1, wherein there is arranged on the flexible circuit board (12) at least one second conductor track (14a-14e) which has a first end region (20a-20e) and a second end region (22a-22e), wherein the conductor track (14a-14e) and the at least second conductor track (14a-14e) run substantially adjacent, in particular parallel, to one another, wherein the at least second conductor track (14a-14e) forms an at least second coil (46).

9. Coil device (10) according to claim 1, wherein the first (20a-20e) and second end regions (22a-22e) of the conductor track (14a-14e) and the first (20a-20e) and second end regions (22a-22e) of the at least second conductor track (14a-14e) are electrically connected to the rigid circuit board (18) such that the first coil (46) and at least second coil (46) are electrically separated coils (46).

10. Coil device (10) according to claim 1, wherein the first (20a-20e) and second end regions (22a-22e) of the conductor track (14a-14e) and the first (20a-20e) and second end regions (22a-22e) of the at least second conductor track (14a-14e) are electrically connected to the rigid circuit board (18) such that the first coil (46) and second coil (46) are shared coils (46).

11. Coil device (10) according to claim 1, wherein the first (20a-20e) and second end regions (22a-22e) of the conductor track (14a-14e) and the first (20a-20e) and second end regions (22a-22e) of the at least second conductor track (14a-14e) are electrically connected to the rigid circuit board (18) such that the first coil (46) and second coil (46) are connected in series.

12. Coil device (10) according to claim 1, wherein the coil device (10) further has a core element (52) which has a ferromagnetic material, in particular ferrite, wherein the core element (52) is arranged inside the coil (46) in a coil plane.

13. Coil device (10) according to claim 1, wherein the flexible circuit board (12) has two lugs (30a, 30b) which extend parallel to the roller axis (R) or folding axis (F), wherein the end regions (20, 22) of the conductor track (14) are arranged on each of the two lugs (30a, 30b).

14. Coil device (10) according to claim 1, wherein a cross section of the rolled up or folded flexible circuit board (12) running transversely, in particular perpendicularly, to the roller axis (R) or folding axis (F) is round, oval, rectangular or square.

15. Coil device (10) according to claim 1, wherein the conductor track (14) runs in a straight, wavy or zigzag pattern on the flexible circuit board (12).

16. Coil device (10) according to claim 1, wherein the flexible circuit board (12) is configured to be multi-layered, wherein the conductor track (14) is arranged in a first layer of the flexible circuit board, wherein a second conductor track is arranged in at least a second layer of the flexible circuit board, wherein end regions of the first and second conductor tracks are arranged on an external surface of the flexible circuit board (12) by means of plated through-holes.

17. Coil device (10) according to claim 1, wherein the conductor track (14) is configured to be at least two-stranded in its middle region.

18. Proximity sensor (11), with a coil device (10) according to claim 1, wherein the proximity sensor (11) is an inductive proximity switch or an inductive distance sensor.

19. Method of producing a coil device (10) for a proximity sensor (11), with the steps:
providing (S1) a flexible circuit board (12), on which is arranged a conductor track (14) which has a first end region (20) and a second end region (22), wherein the flexible circuit board (12) is rolled up around a roller axis (R) or folded around a folding axis (F) such that the conductor track (14) forms a coil (46);
providing (S3) a rigid circuit board (18) for electrically connecting at least one electronic component (24);
providing (S2) an electrical connecting element (16); and
electrically connecting (S4) each of the first end region (20) and the second end region (22) to the rigid circuit board (18) by means of the electrical connecting element (16).
